(19) United States
(12) Patent Application Publication
(10) Pub. No.: US 2007/0128797 A1
(43) Pub. Date: Jun. 7, 2007

(54) Flash memory device and method for fabricating the same

(75) Inventor: Jung-II Cho, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/475,632

(22) Filed: Jun. 27, 2006

(30) Foreign Application Priority Data
Dec. 7, 2005 (KR) 2005-0118919

(51) Int. Cl. H01L 21/336; H01L 29/76

(52) U.S. Cl. 438/257; 257/314

(57) ABSTRACT

A flash memory device and a method for fabricating the same are provided. The method includes: preparing a semi-finished substrate where floating gates and an isolation layer isolating the floating gates are formed; recessing a predetermined portion of the isolation layer to make the floating gates protrude; etching another predetermined portion of the isolation layer to form a trench therein; forming a dielectric layer over the isolation layer and the floating gates; and forming a control gate over the dielectric layer such that the control gate fills the trench.

### FIELD OF THE INVENTION

The present invention relates to a semiconductor memory device and a method for fabricating the same; and more particularly, to a flash memory device and a method for fabricating the same.

### DESCRIPTION OF RELATED ARTS

In a flash memory device, as a cell threshold voltage distribution becomes narrow, program operation becomes faster and is increasingly advantageous in respect of reliability. In flash memory devices, capacitance exists between cells, and as the device size becomes smaller, the cell size also becomes smaller. Thus, the distance between the cells decreases, and as a result, interference caused by the capacitance existing between the cells is more likely to occur. This fact further causes a threshold voltage distribution of a programmed cell to become wide.

During cell operation, if peripheral cells are programmed, the interference causes a threshold voltage of the programmed peripheral cells to increase to a greater extent as compared with the erased peripheral cells. Particularly, depending on a state of the peripheral cells, a programming state of the target cell is being affected, resulting in an increase of the threshold voltage distribution of the programming state in the entire device.

Currently, among nonvolatile memory devices, a typical device isolation scheme for 70 nm level flash memory devices (e.g., NAND flash memory devices) is a self-aligned shallow trench isolation (SA-STI) process, including: defining a profile of a gate electrode using a thin polysilicon layer, which becomes a part of a floating gate, to secure a certain quality of a gate insulation layer (or a tunnel oxide layer); and performing an isolation process.

Hereinafter, the aforementioned SA-STI process will be described in detail.

FIGS. 1A to 1C are cross-sectional views illustrating a typical method for fabricating a flash memory device.

Referring to FIG. 1A, a tunnel oxide layer 22, a first polysilicon layer 23 for use in a floating gate, a pad oxide layer 24, and a pad nitride layer 25 are sequentially formed on a substrate 21. A photolithography process is performed thereon to sequentially etch the pad nitride layer 25, the pad oxide layer 24, the first polysilicon layer 23, the tunnel oxide layer 22, and the substrate 21. After the photolithography process, a plurality of trenches 26 are formed within the substrate 21. An oxidation process is performed to form an oxide layer (not shown) on sidewalls of the trenches 26.

Although not illustrated, on the above resulting structure, a gap-filling insulation layer is formed thickly enough to fill at least the trenches 26. The gap-filling insulation layer is formed of a high density plasma (HDP) oxide material. A chemical mechanical polishing (CMP) process is performed to planarize the gap-filling insulation layer until the pad nitride layer 25 is exposed. After the CMP process, the gap-filling insulation layer becomes isolated. The isolated gap-filling insulation layers are denoted as reference numeral 27, and will be referred to as “isolation layers.”

Referring to FIG. 1B, a wet etching process is performed using phosphoric acid (H₃PO₄) to remove the pad nitride layer 25. Using a wet chemical such as fluoric acid (HF) or buffered oxide etchant (BOE), the isolation layers 27 are etched with a predetermined thickness D. At this point, the pad oxide layer 24 may be removed after the pad nitride layer 25 is removed, or while the isolation layers 27 are etched. Reference numeral 27A denotes this patterned isolation layers 27. Particularly, the target etch thickness D of the isolation layers 27 are determined in a range that does not allow an exposure of the tunnel oxide layer 22.

Referring to FIG. 1C, a dielectric layer 28 and a second polysilicon layer 29 for use in a control gate are sequentially formed on the resulting structure illustrated in FIG. 1B. Although not illustrated, a photolithography process is performed to etch the second polysilicon layer 29. After the photolithography process, floating gates that are isolated by the patterned isolation layers 27A are formed.

FIG. 2 is a diagram illustrating a limitation associated with the above typical fabrication method.

As illustrated, a factor in increasing interference may exist in a diagonal direction between word lines, or between bit lines. Particularly, with respect to the direction from the bit line to the bit line, the interference may increase due to capacitance between polysilicon layers. That is, enlarging the distance between the polysilicon layers may reduce the capacitance.

As described above, the distance between the polysilicon layers needs to be enlarged to decrease the capacitance between the polysilicon layers. However, in a structure obtained using the typical SA-STI process, enlarging the distance between the polysilicon layers often causes the area of an active region to be decreased. The decrease in the area of the active region may become a factor in reducing a program operation speed.

### SUMMARY OF THE INVENTION

It is, therefore, an object of the present invention to provide a flash memory device capable of decreasing a threshold voltage distribution by reducing capacitance between adjacent floating gates and a method for fabricating the same.

In accordance with an aspect of the present invention, there is provided a method for fabricating a flash memory device, including: preparing a semi-finished substrate where floating gates and an isolation layer isolating the floating gates are formed; recessing a predetermined portion of the isolation layer to make the floating gates protrude; etching another predetermined portion of the isolation layer to form a trench therein; forming a dielectric layer over the isolation layer and the floating gates; and forming a control gate over the dielectric layer such that the control gate fills the trench.

In accordance with another aspect of the present invention, there is provided a flash memory device, including: a tunnel oxide layer formed over a substrate; floating gates formed over the tunnel oxide layer; an isolation layer isolating the floating gates and comprising a trench with a predetermined depth in a central region of the isolation layer; a dielectric layer formed over the floating gates and the isolation layer; and a control gate formed over the dielectric layer such that the control gates fills the trench.

### BRIEF DESCRIPTION OF THE DRAWINGS

The above and other objects and features of the present invention will become better understood with respect to the following description of the exemplary embodiments given in conjunction with the accompanying drawings, in which:

FIGS. 1A to 1C are cross-sectional views illustrating a typical method for fabricating a flash memory device;

FIG. 2 is a diagram illustrating a limitation associated with the typical fabrication method;

FIG. 3 is a cross-sectional view illustrating a structure of a flash memory device in accordance with an embodiment of the present invention; and

FIGS. 4A to 4G are cross-sectional views illustrating a method for fabricating a flash memory device in accordance with an embodiment of the present invention.

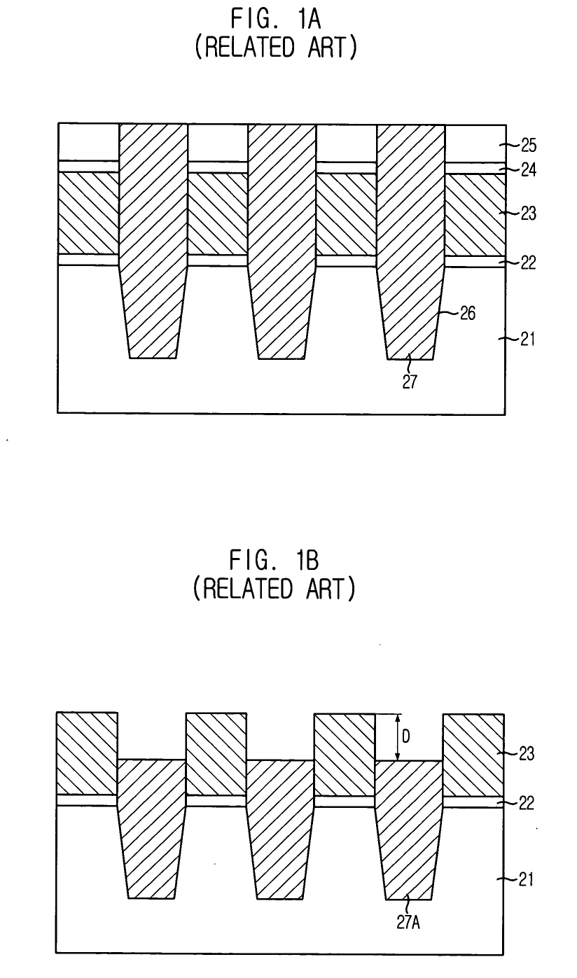

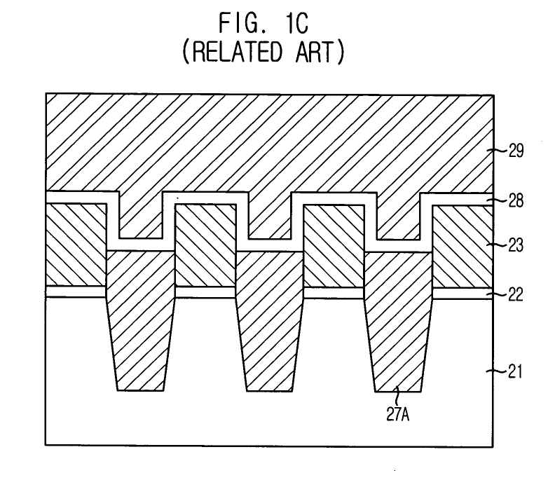

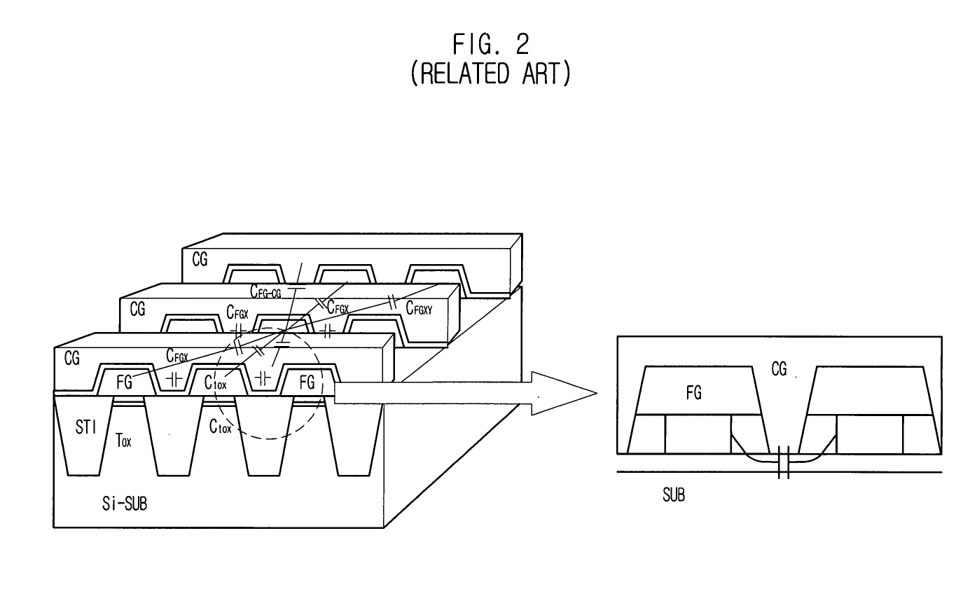

### DETAILED DESCRIPTION OF THE INVENTION

Hereinafter, embodiments of the present invention will be described in detail with reference to the accompanying drawings.

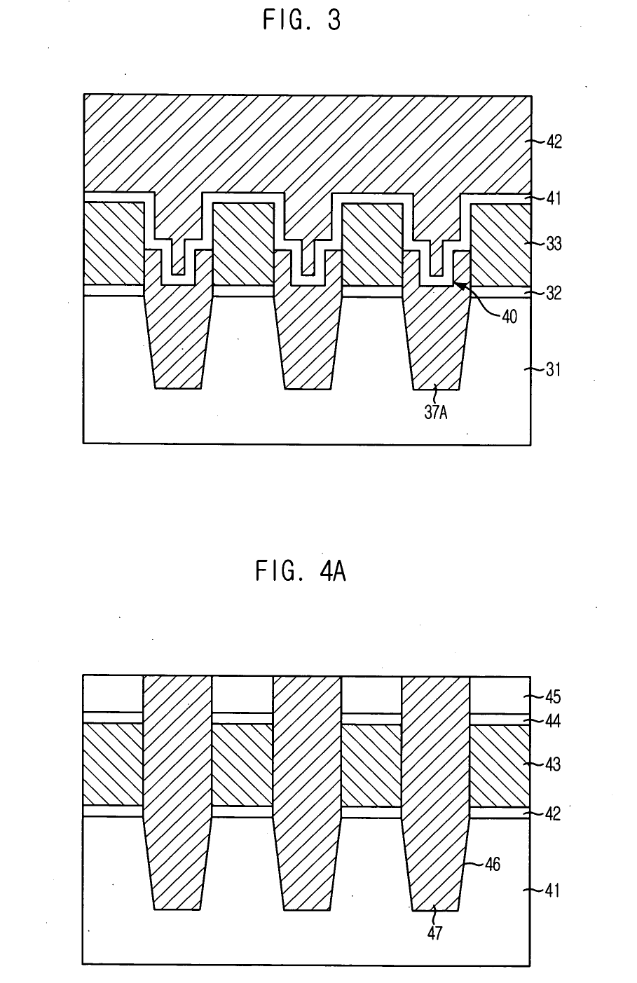

FIG. 3 is a cross-sectional view illustrating a structure of a flash memory device in accordance with an embodiment of the present invention.

As illustrated, floating gates 33 are formed over certain regions of a substrate 31, and a tunnel oxide layer 32 is formed beneath the floating gates 33. Separated isolation layers 37A are formed in regions of the substrate 31 beneath the sidewalls of the floating gates 33. Trenches 40 are formed individually in top central portions of the separated isolation layers 37A. A dielectric layer 41 is formed over the floating gates 33 and the separated isolation layers 37A, and a control gate 42 is formed over the dielectric layer 41.

The floating gates 33 are formed to a thickness ranging from approximately 800 Å to approximately 1,200 Å. The dielectric layer 41 is formed in a structure of oxide/nitride/oxide (ONO). The floating gates 33 and the control gate 42 include polysilicon.

The above illustrated structure can improve a program operation speed by reducing capacitance between the floating gates 33. The capacitance reduction can be achieved by forming a conductive material (e.g., polysilicon) between the adjacent floating gates 33 separated by the separated isolation layers 37A.

Hereinafter, a method for fabricating the above illustrated flash memory device will be described in detail.

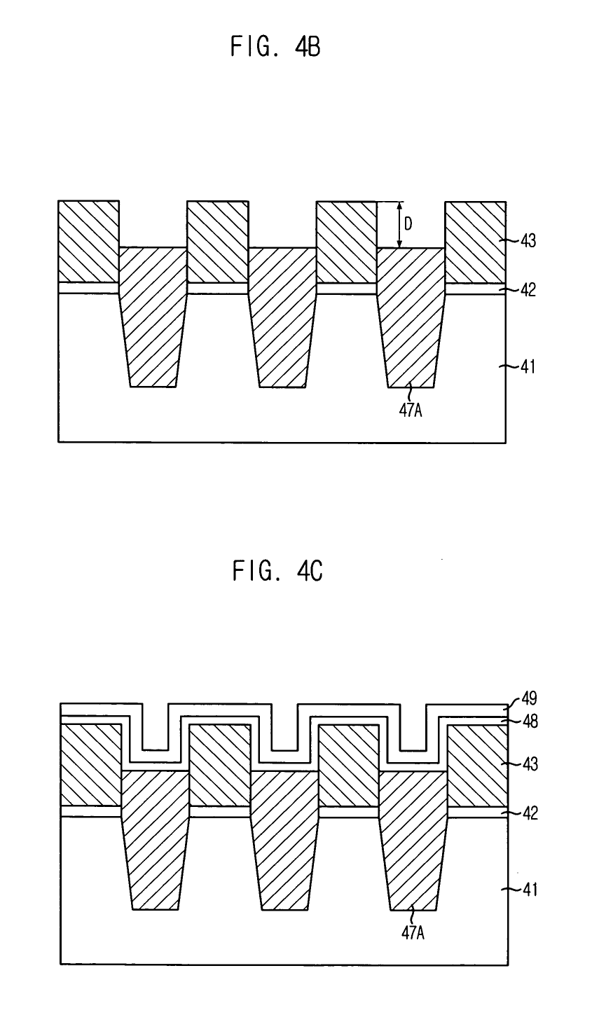

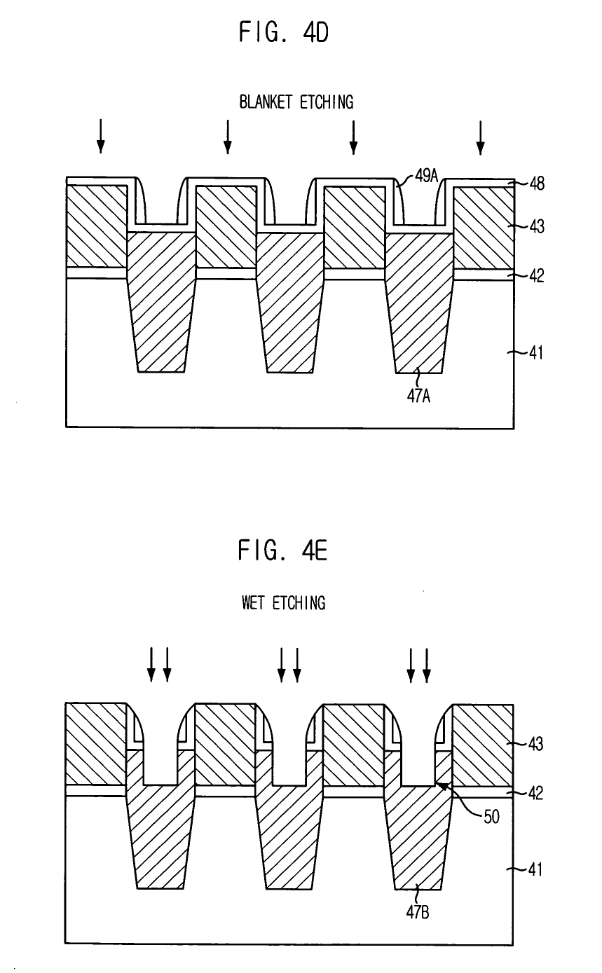

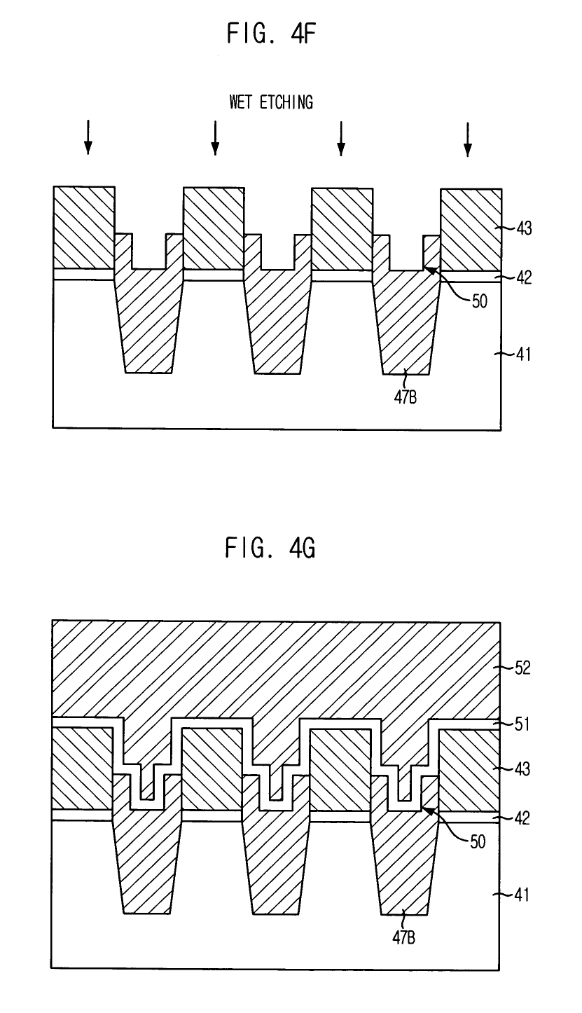

FIGS. 4A to 4G are cross-sectional views illustrating a method for fabricating a flash memory device in accordance with an embodiment of the present invention.

Referring to FIG. 4A, a tunnel oxide layer 42, a first polysilicon layer 43 for use in a floating gate, a pad oxide layer 44, and a pad nitride layer 45 are sequentially formed over a substrate 41. A photolithography process is performed to sequentially etch the pad nitride layer 45, the pad oxide layer 44, the first polysilicon layer 43, the tunnel oxide layer 42, and the substrate 41. After the photolithography process, a plurality of first trenches 46 are formed in the substrate 41. An oxidation process is performed to form an oxide layer on sidewalls of the first trenches 46.

Although not illustrated, a gap-filling insulation layer is formed over the above resulting structure to cover the first trenches 46. The gap-filling insulation layer includes a HDP oxide based material. A CMP process is performed on the gap-filling insulation layer until the pad nitride layer 45 is exposed. After the CMP process, the gap-filling insulation layer is planarized and isolated from each other. The isolated gap-filling insulation layers are denoted with reference numeral 47 and will be referred to as “isolation layers.”

Referring to FIG. 4B, a wet etching process is performed using phosphoric acid (H₃PO₄) to remove the pad nitride layer 45. The isolation layers 47 are etched with a predetermined thickness D using a wet chemical including fluoric acid (HF) or buffered oxide etchant (BOE). Particularly, the isolation layers 47 are etched under the target of not exposing the tunnel oxide layer 42. At this point, the pad oxide layer 44 may be removed after the pad nitride layer 45 is removed, or while the isolation layers 47 are etched. Herein, reference numeral 47A denotes the isolation layers that are separated by the above wet etching process and will be referred to as “separated isolation layers.”

Referring to FIG. 4C, a sacrificial layer 48 and a spacer nitride layer 49 are formed over the first polysilicon layer 43 and the separated isolation layers 47A. More specifically, the sacrificial layer 48 includes an oxide based material and is formed to a thickness ranging from approximately 10 Å to approximately 100 Å. The spacer nitride layer 49 is formed to a thickness ranging from approximately 100 Å to approximately 200 Å. The sacrificial layer 48 is formed to reduce damage, which often occurs when the first polysilicon layer 43 is exposed during a subsequent removal of the spacer nitride layer 49 using phosphoric acid (H₃PO₄).

The thickness of the spacer nitride layer 49 is critical. The spacer nitride layer 49 needs to have at least certain thickness. Particularly, the thickness of the spacer nitride layer 49 needs to be less than a distance between the first polysilicon layers 43 to allow performance of an etching process within the regions between the first polysilicon layers 43.

If the spacer nitride layer 49 is formed too thinly, device reliability is more likely to be degraded due to capacitance existing between the substrate 41 and a second polysilicon layer 52 (see FIG. 4G).

Referring to FIG. 4D, a blanket etching process is performed to etch the spacer nitride layer 49. After the blanket etching process, spacers 49A are formed. At this point, blanket etching process is performed to make the sacrificial layer 48 remain over the first polysilicon layer 43. The remaining sacrificial layer 48 serves a role in blocking the first polysilicon layer 43 from being exposed when the spacers 49A are removed using phosphoric acid (H₃PO₄).

Referring to FIG. 4E, an etching process is performed using the spacers 49A as an etch barrier to form second trenches 50 in top central portions of the separated isolation layers 47A. The second trenches 50 are formed to have a predetermined range of width and depth that allow the second polysilicon layer 52, which is to be formed over the second trenches 50, to block the capacitance between the first polysilicon layers 43. The above etching process may be a wet etching process. The wet etching process is performed such that the second polysilicon layer 52 (see FIG. 4G) can fills the space between the first polysilicon layers 43 to obtain the isolation of the first polysilicon layer 43 (i.e., the floating gates). Herein, reference numeral 47B denotes patterned isolation layers.

Referring to FIG. 4F, the spacers 49A formed on the sidewalls of the first polysilicon layers 43 are removed using phosphoric acid (H₃PO₄). The sacrificial layer 48 remaining over the first polysilicon layer 43 is also removed using HF solution or BOE solution.

Referring to FIG. 4G, a dielectric layer 51 and the aforementioned second polysilicon layer 52 are sequentially formed over the patterned isolation layers 47B and over the first polysilicon layer 43. The dielectric layer 51 is formed in an ONO structure, and the second polysilicon layer serves as control gates.

As described above, the isolation layers are selectively wet etched such that the conductive material for the control gates, e.g., polysilicon, can fill the space between the first polysilicon layers (i.e., the floating gates) to thereby obtain the isolation of the first polysilicon layer. As a result, capacitance between the first polysilicon layers can be reduced, and this decrease of the capacitance allows an improvement on device operation speed.

The present application contains subject matter related to the Korean patent application No. KR 2005-0118919, filed in the Korean Patent Office on Dec. 7, 2005, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A method for fabricating a flash memory device, comprising:
preparing a semi-finished substrate where floating gates and an isolation layer isolating the floating gates are formed;
recessing a predetermined portion of the isolation layer to make the floating gates protrude;
etching another predetermined portion of the isolation structure to form a trench therein;
forming a dielectric layer over the isolation structure; and
forming a control gate over the dielectric layer such that the control gate fills the trench.

2. The method of claim 1, wherein the etching of the other predetermined portion to form the trench comprises:
forming a sacrificial layer over the protruding floating gates and the recessed isolation structure;
forming spacers over sidewalls of the sacrificial layer disposed over the recessed isolation structure;
performing an etching process using the spacers as an etch barrier to recess the other predetermined portion of the isolation layer disposed between the spacers; and
removing the spacers and the sacrificial layer.

3. The method of claim 2, wherein the spacers include a nitride based material.

4. The method of claim 3, wherein the removing of the spacers is carried out using a chemical containing a family of phosphoric acid.

5. The method of claim 4, wherein the chemical includes H₃PO₄.

6. The method of claim 3, wherein the forming of the spacers comprises:
forming a nitride based layer over the sacrificial layer; and
performing a blanket etching process using the sacrificial layer as an etch barrier to etch the nitride based layer.

7. The method of claim 2, wherein the sacrificial layer includes an oxide based material.

8. The method of claim 7, wherein the removing of the sacrificial layer is carried out using one of a HF based chemical and buffered oxide etchant (BOE).

9. The method of claim 8, wherein the HF based chemical includes a HF solution.

10. The method of claim 7, wherein the sacrificial layer is formed to a thickness ranging from approximately 10 Å to approximately 100 Å.

11. The method of claim 10, wherein the dielectric layer is formed in a structure of oxide/nitride/oxide (ONO).

12. The method of claim 11, wherein the floating gates and the control gate include polysilicon.

13. A flash memory device, comprising:
a tunnel oxide layer formed over a substrate;
floating gates formed over the tunnel oxide layer;
an isolation layer isolating the floating gates and comprising a trench therein with a predetermined depth;
a dielectric layer formed over the floating gates and the isolation layer; and
a control gate formed over the dielectric layer such that the control gate fills the trench.

14. The flash memory device of claim 13, wherein the trench does not expose the tunnel oxide layer.

15. The flash memory device of claim 13, wherein a bottom portion of the trench is formed lower than the bottom portion of each of the floating gates.

16. The flash memory device of claim 15, wherein the dielectric layer is formed in a structure of oxide/nitride/oxide.

17. The flash memory device of claim 16, wherein the floating gates and the control gate include polysilicon.
